(19) United States
(12) Patent Application Publication
(10) Pub. No.: US 2025/0271283 A1
(43) Pub. Date: Aug. 28, 2025

(54) LOCATING, IN A VEHICLE, ONE OR MORE PERIPHERALS

(71) Applicant: VALEO COMFORT AND DRIVING ASSISTANCE, Créteil (FR)

(72) Inventors: Angelo Colosimo, Créteil (FR); Christophe Gueble, Créteil (FR); Pierre Demeyer, Créteil (FR); Christophe Aubreton, Créteil (FR); Sathish Muralikrishnan, Créteil (FR); Joel Pature, Créteil (FR)

(73) Assignee: VALEO COMFORT AND DRIVING ASSISTANCE, Créteil (FR)

(21) Appl. No.: 18/704,960

(22) PCT Filed: Oct. 10, 2022
(86) PCT No.: PCT/EP2022/078063

§ 371 Date: Apr. 26, 2024

(30) Foreign Application Priority Data
Oct. 26, 2021 (FR) FR2111367

(51) Int. Cl. G01D 5/14; G01R 19/14

(52) U.S. Cl. CPC G01D 5/14; G01R 19/14

(57) ABSTRACT

A method for locating, in a vehicle, one or more peripherals is disclosed. The vehicle includes a central power supply which includes connectors, each in a different position in the vehicle from among a predetermined plurality of positions. The vehicle includes at least two groups, each of one or more respective connectors. Each peripheral is connected to the central power supply via a respective connector of a respective group. The method includes, for each peripheral, taking an electrical measurement of the polarity of connection between the peripheral and the central power supply. The method also includes determining, according to the value of the measurement, a group of one or more positions from among the predetermined plurality of positions of the peripherals.

### TECHNICAL FIELD

The present disclosure relates to locating, in a vehicle, one or more peripherals.

### TECHNICAL BACKGROUND

There are nowadays vehicles comprising one or more peripherals installed in the vehicle. These peripherals make it possible to execute functions by means of the vehicle, such as locating a portable device such as a fob, a key or a smartphone. For example, the vehicle may order the vehicle to be opened when its owner approaches the vehicle by locating, with the aid of peripherals, the key carried by the owner in proximity to the vehicle. For this purpose, the peripherals may be installed in various positions in the vehicle and may communicate with the portable device in order to locate it.

In executing such functions, the vehicle generally uses the position of the one or more peripherals in the vehicle. However, the position of each of the one or more peripherals is not initially known by the vehicle. Indeed, at the time of installation or during a repair, the same peripheral may be installed in various positions in the vehicle. In other words, at least some of the peripherals of the vehicle are interchangeable.

Moreover, manually recording the location of each peripheral in the vehicle after each peripheral installation or replacement would take a long time and be difficult, and is therefore not optimal.

That is why there is a need to improve the location, in a vehicle, of one or more peripherals.

### SUMMARY

For this purpose a method for locating, in a vehicle, one or more peripherals is proposed. The vehicle comprises a central power supply having connectors, each in a different position in the vehicle from among a predetermined plurality of positions. The vehicle comprises at least two groups, each of one or more respective connectors. Each peripheral is connected to the central power supply via a respective connector of a respective group. Each peripheral is adapted to be connected to at least one respective connector of each other group. The connectors to which each peripheral is adapted to be connected together form a respective plurality of connectors, each defining a polarity of connection between the peripheral and the unique central power supply for each group. The method comprises, for each peripheral, an electrical measurement exhibiting a different signature according to the polarity of connection between the peripheral and the central power supply, and determining, according to the value of the measurement, a group of one or more positions from among the predetermined plurality of positions.

The method improves the location, in the vehicle, of the one or more peripherals. Indeed, the method makes it possible to determine which group each peripheral belongs to.

Furthermore, the method improves the preparation and the maintenance of the one or more peripherals in the vehicle. Indeed, the method makes it possible to locate each of the peripherals without each peripheral being adapted to be connected to a single unique connector of the central power supply. For example, all the peripherals of the vehicle may each be interchanged with at least one other peripheral of the vehicle. The method thus makes it possible to install the same peripheral in various positions in the vehicle, which makes it easier to prepare the vehicle and replace the one or more peripherals.

Moreover, the location of the one or more peripherals is particularly robust. Indeed, the electrical measurement makes it possible to distinguish the groups quickly and accurately. Notably, the measurement uses the power supply of each of the one or more peripherals directly, which makes it possible to avoid using a dedicated additional connection.

Each connector may comprise a connection interface and each peripheral may comprise a connection interface. For each peripheral and each connector in its respective plurality of connectors, the connection interface of the peripheral may be able to be connected to the connection interface of the connector according to a predetermined arrangement.

The central power supply may comprise a set of poles and the connection interface of each connector may comprise a set of connection points. Each pole of the central power supply may be electrically connected to a respective connection point of the connection interface of each connector. The set of poles of the central power supply may be electrically connected to the set of connection points of the connection interface of each connector in each respective plurality of connectors according to a unique correspondence for each group.

The set of poles of the central power supply may comprise a power supply pole and a ground pole. Each peripheral may comprise an electrical circuit including several sub-circuits, each having a distinct respective connection terminal, a first common pole and a second common pole. Each sub-circuit may be configured to stop current from flowing from the first pole to the connection terminal and to stop current from flowing from the connection terminal to the second pole, and so that, when the current flows from the connection terminal to the first pole, then the connection terminal and the first pole may be at the same potential, and, when the current flows from the second pole to the connection terminal, then the second pole and the connection terminal may be at the same potential. Each peripheral may be adapted so that, for each connector in its respective plurality of connectors, the connection terminal of each sub-circuit is connected to a distinct respective connection point of the connection interface of the connector, with at least the connection terminal of one sub-circuit connected to the connection point connected to the power supply pole and the connection terminal of another sub-circuit connected to the connection point connected to the ground pole.

Each sub-circuit of each peripheral may comprise a first diode configured to stop current from flowing from the first pole to the connection terminal and a second diode configured to stop current from flowing from the connection terminal to the second pole.

Each sub-circuit of each peripheral may comprise a respective resistor. The electrical measurement may comprise, for each resistor, a respective measurement of voltage across the terminals of the respective resistor.

Each group may consist of a single connector. Each group may correspond to a respective position in the vehicle.

Each group may comprise several connectors. The method may further comprise, for each group, providing the position of a reference peripheral, relatively locating each other peripheral, and determining the position of each other peripheral in accordance with the relative location and with the position of the reference peripheral.

Each peripheral of a group may be a reference peripheral of each group. For example, each peripheral may be the reference peripheral of the group to which it belongs. The relative location may comprise a measurement of distance between each other peripheral and the reference peripheral.

The measurement may be a time-of-flight measurement.

A computer program comprising instruction codes for executing, by means of a processor, the location method is also proposed.

A computer-readable storage medium on which the computer program is stored is also proposed.

A peripheral adapted to be connected, via a connector, to a central power supply of a vehicle is also proposed. The peripheral is configured to implement the location method.

A system for a vehicle is also proposed. The system may comprise a processor and a memory on which the computer program is stored. Alternatively or additionally, the system may comprise one or more peripherals.

### BRIEF DESCRIPTION OF THE FIGURES

Non-limiting examples will be described with reference to the following figures:

FIG. 1 depicts an example of a vehicle comprising a central power supply having connectors.

FIG. 2 depicts an example of a connector of the central power supply of the vehicle of FIG. 1.

FIG. 3 depicts a first example of an electrical circuit of a peripheral.

FIG. 4 depicts an example of the variation in signature exhibited by the measurement in accordance with the polarity of connection for the first example of an electrical circuit of FIG. 3.

FIG. 5 depicts a second example of an electrical circuit of a peripheral.

FIG. 6 depicts an example of the variation in signature in accordance with the polarity of connection for the second example of an electrical circuit of FIG. 5.

FIG. 7 depicts an example of determining the position of each anchor.

FIG. 8, FIG. 9 and FIG. 10 depict various examples of groups of connectors.

### DETAILED DESCRIPTION

A method for locating, in a vehicle, one or more peripherals is proposed. The vehicle comprises a central power supply having connectors, each in a different position in the vehicle from among a predetermined plurality of positions. The vehicle comprises at least two groups, each of one or more respective connectors. Each peripheral is connected to the central power supply via a respective connector of a respective group. Each peripheral is adapted to be connected to at least one respective connector of each other group. The connectors to which each peripheral is adapted to be connected together form a respective plurality of connectors, each defining a polarity of connection between the peripheral and the unique central power supply for each group. The method comprises, for each peripheral, an electrical measurement exhibiting a different signature according to the polarity of connection between the peripheral and the central power supply, and determining, according to the value of the measurement, a group of one or more positions from among the predetermined plurality of positions.

The group of one or more positions which is determined by the method is the one corresponding to the group of one or more connectors defining the polarity of connection which is associated with the signature of the electrical measurement carried out by the method. In other words, the one or more positions of the determined group are the one or more positions of the one or more connectors defining the polarity of connection corresponding to the signature of the electrical measurement. Indeed, the polarity of connection defined by the connectors to which the same peripheral is adapted to be connected is unique for each group. Likewise, the signature of the electrical measurement is different according to the polarity of connection, and therefore unique for each group. The signature exhibited by the electrical measurement therefore makes it possible to determine which group each peripheral belongs to, which makes it possible to distinguish the peripherals of different groups which are adapted to be connected to various connectors of different groups interchangeably.

The one or more peripherals may comprise or consist of one or more electronic modules, one or more items of equipment and/or one or more anchors. Each peripheral may comprise an electrical circuit configured to implement one or more functions, such as communicating with a master unit and/or a portable device. For example, the peripheral may be configured to transmit signals to the master unit and/or the portable device and/or receive some.

Each peripheral is connected to the central power supply via a respective connector, that is to say that each peripheral is supplied with power by the central power supply of the vehicle, via the respective connector. The central power supply of the vehicle therefore provides electrical energy to each of the peripherals. The central power supply of the vehicle may comprise a battery.

The predetermined plurality of positions comprises all of the positions of the connectors of the vehicle. The number of connectors and the position of each connector may vary from one vehicle to another. The plurality of positions is determined before the method is executed, for example when the vehicle is manufactured, or during maintenance on the vehicle. While the vehicle is being brought into operation, for example, the plurality of positions may be stored. For example, the vehicle may comprise an electrical circuit comprising a memory on which the predetermined plurality of positions is stored. The predetermined plurality of positions may be stored on the memory in the form of a table comprising, for each position, a unique identifier associated with spatial coordinates (for example, X, Y and Z spatial coordinates). Each position may also or alternatively be identified according to its relative location in the vehicle (for example “front left” or “inside back”).

The groups of one or more connectors each correspond to a group of one or more positions in the predetermined plurality of positions. The groups together form a partition of the plurality of positions. The method may use any type of partitioning of the plurality of positions of connectors. For example, the groups of one or more positions may be defined according to one or more directions of the vehicle (for example, along the length or along the width of the vehicle). For example, the plurality of positions may comprise a first group of positions which are located at the front of the vehicle and a second group of positions which are located at the back of the vehicle.

The groups of one or more positions may also be defined according to locations of the vehicle. For example, the plurality of positions may comprise a first group of positions which are located in the passenger compartment of the vehicle and a second group on the outside around the perimeter of the vehicle. When each group comprises only one position, the plurality of positions may comprise a first group of a connector at the front left of the vehicle, a second group of a connector at the front right, a third group of a connector at the back left and a fourth group of a connector at the back right.

In some examples, each group comprises a single position. In these examples, location ends when the groups are determined and therefore when the method determines the position of each peripheral individually. In other examples, at least one group (for example, all the groups) comprises several positions. In this case, the method determines the groups of peripherals, and therefore does not necessarily determine the position of each peripheral individually, but may comprise subsequently individually locating each peripheral by means of other means. Examples of such implementations are provided below.

The polarity of connection is a correspondence of the poles of the central power supply to poles of the peripheral. In other words, as all of the poles of the peripheral comprise at least two distinguishable poles and all of the poles of the power supply likewise comprise at least two distinguishable poles, the polarity of connection is defined by the combinatorics selected to connect the poles of the power supply with said poles of the peripheral.

The method comprises, for each peripheral, an electrical measurement exhibiting a different signature according to the polarity of connection between the peripheral and the central power supply. The electrical measurement is a measurement carried out on the basis of the current supplying power to the peripheral. The electrical measurement may comprise any sort of measurement on the power supply current. For example, the electrical measurement may comprise measurements across the terminals of one or more components supplied with power by the current, for example measurements of voltage or of current. The signature is a distinctive mark which the electrical measurement exhibits according to the polarity of connection, that is to say, for example, one or more distinctive features which the measurements of voltage comprise. The electrical measurement may, for example, comprise a vector of several measurements of voltage or other electrical property, each across the terminals of a different terminal supplied with power by the current, said several measurements being ordered (for example, following a predetermined order between the components). In this case, the signature may depend on the relative values of the vector which is obtained by the several measurements. For example, the signature may consist of a reference vector of values from among a predetermined set of reference vectors (each reference vector corresponding to the theoretical values obtained for the given polarity of connection).

Each peripheral may be configured to carry out the electrical measurement itself, that is to say automatically. In this case, the method may comprise communicating (for example, automatically) the value of the measurement to a processor, for example a processor of the vehicle executing the method. The method may be executed automatically after one or more of the peripherals are installed or replaced.

The method comprises determining, according to the value of the measurement, a group of one or more positions from among the predetermined plurality of positions. In other words, the method associates each signature with a given group and the relationship between group and signature is known before the method is executed. For example, the relationship between group and signature may be defined within a database or a table.

The determination may comprise comparing the value of the measurement with one or more predetermined measurement values, which may each correspond to a group. In the case where the electrical measurement comprises a vector of several measurements, the determination may comprise comparing the value of each of the measurements of the vector with a vector of expected values for each given position, for example stored within the database or the table. For example, the database or the table may comprise, for each position in the vehicle, a respective vector of expected values. The comparison may comprise, for each position, extracting, from the database or the table, the vector of expected values for the position and calculating a difference between the measured values and the expected values of the position. The method may next deduce that the position of the peripheral is the one for which the difference is the smallest. The difference may be expressed in the form of a Boolean (for example “true” when the measured and expected values are close, and “false” when they are not) or of a continuous quantity, for example the standard of the difference between the two vectors (the vector of measured values and the vector of expected values). The comparison may be made taking account of one or more potential measurement variation errors.

The database or the table may be stored before the method is executed, for example on a memory of the vehicle. In this case, the method may extract the vectors of expected values from the memory of the vehicle. Alternatively, the database or the table may be stored on a server. In this case, the method may communicate with the server in order to obtain the vectors of expected values.

The method may simultaneously determine the group of each of the peripherals, that is to say carry out the electrical measurement and determine the group at the same time for each peripheral. Alternatively, the method may successively determine, for each of the connectors, which group it belongs to. In this case, the method may take into account the groups already recognized for the preceding connectors.

In a first implementation of the method, each group consists of a single connector. Each group then corresponds to a respective position in the vehicle. Each peripheral is adapted to be connected to each of the connectors (that is to say the one to which it is connected and all the other connectors), which makes it easier to produce, install and maintain the peripherals. Indeed, the same peripheral may be used for each of the positions in the vehicle. In other words, this first example of an implementation amounts to not having a group and to considering the connectors individually. Each connector defines a polarity of connection between the peripheral and the central power supply which is unique, that is to say distinct from the polarities of connection of each other connector. The electrical measurement therefore exhibits a different signature for each peripheral, which makes it possible for the method to determine which connector each of the peripherals is connected to. The method may next deduce therefrom the position of each peripheral individually, for example on the basis of a table listing the position of each connector, for example stored on a memory connected to the processor of the vehicle executing the method.

In a second implementation of the method, each group may comprise several respective connectors. Each group then corresponds to several positions in the predetermined plurality of positions. The connectors to which the same peripheral is adapted to be connected and which belong to different groups each define a distinct polarity of connection. Between the groups, the polarity of connection is therefore different for these connectors. Within each group, in the case where a peripheral is adapted to be connected to several connectors of this group, the polarity of connection defined by each of these connectors is identical. The method determines the groups of peripherals, which therefore makes it possible to locate each of the one or more peripherals from among groups of positions.

In the second implementation, the preparation and the maintenance of the one or more peripherals in the vehicle are also improved. Indeed, each peripheral of each group may be interchanged with at least one other peripheral of another group.

In the second implementation, the method may next comprise individually locating each of the peripherals within each group. In this case, the result amounts to the one obtained in the first implementation of the method.

In the second implementation, each peripheral may be the reference peripheral of each group, for example the reference peripheral of the group to which it belongs. The relative location may comprise a measurement of distance between each other peripheral and the reference peripheral. For example, the peripheral and the reference peripheral may be configured to communicate with one another. For this purpose, the peripheral and the reference peripheral may each comprise components configured to exchange signals with one another, for example a transmitter and a receiver. In some examples, the peripheral and the reference peripheral may communicate using a short-range wireless communication protocol, for example the UWB (ultra-wideband) communication protocol. In some examples, each peripheral may be an anchor and the reference peripheral of each group may be a reference anchor.

In the second implementation, the measurement may be a time-of-flight measurement. For example. The time of flight may be the time taken by a signal to go from the peripheral to the reference peripheral or vice versa. The measurement may comprise exchanging one or more signals between the peripheral and the reference peripheral and measuring the time of flight on the basis of the one or more signals. The measurement of the distance may next be deduced from this time of flight.

Each connector may comprise a connection interface. Each peripheral may likewise comprise a connection interface. For each peripheral and each connector in its respective plurality of connectors, the connection interface of the peripheral may be able to be connected to the connection interface of the connector according to a predetermined arrangement. In other words, the arrangement between the interfaces is unique and fixed for each peripheral and each connector in its respective plurality of connectors. The arrangement fixes the manner and the direction of the connection between the two connection interfaces, that is to say the correspondence of the poles of the connector and of the peripheral at the time of connection. The predetermined polarity of connection is therefore defined by this arrangement.

The arrangement may be predetermined by particular shapes of the connection interface of the connector and of the connection interface of the peripheral which interact with one another in a unique and predetermined manner. For example, the connection interface of the peripheral and the connection interface of the connector may have a complementary shape so that they interlock with one another only in a single direction, that is to say with the same correspondence of the poles of connector to the poles of the peripheral.

For each connector other than the respective plurality of connectors, the connection interface of the peripheral may be unable to be connected to the connection interface of the connector. For example, the interfaces may be physically incompatible or indeed comprise a different distinctive sign (such as a colour or an acronym) in order to signify an incompatibility between the interfaces.

The predetermined arrangement of the connection interfaces improves the robustness of the location. Indeed, it improves the reliability of the distinction between the various groups. Furthermore, the predetermined arrangement of the connection interfaces makes it possible to avoid errors when the one or more peripherals are installed and makes it easier to connect them.

The central power supply may comprise a set of poles. The connection interface of each connector may comprise a set of connection points. For example, the set of connection points of the connector may be a set of pins. Each pole of the central power supply may be electrically connected to a respective connection point of the connection interface of each connector. The set of poles of the central power supply may be electrically connected to the set of connection points of the connection interface of each connector in each respective plurality of connectors according to a unique correspondence for each group.

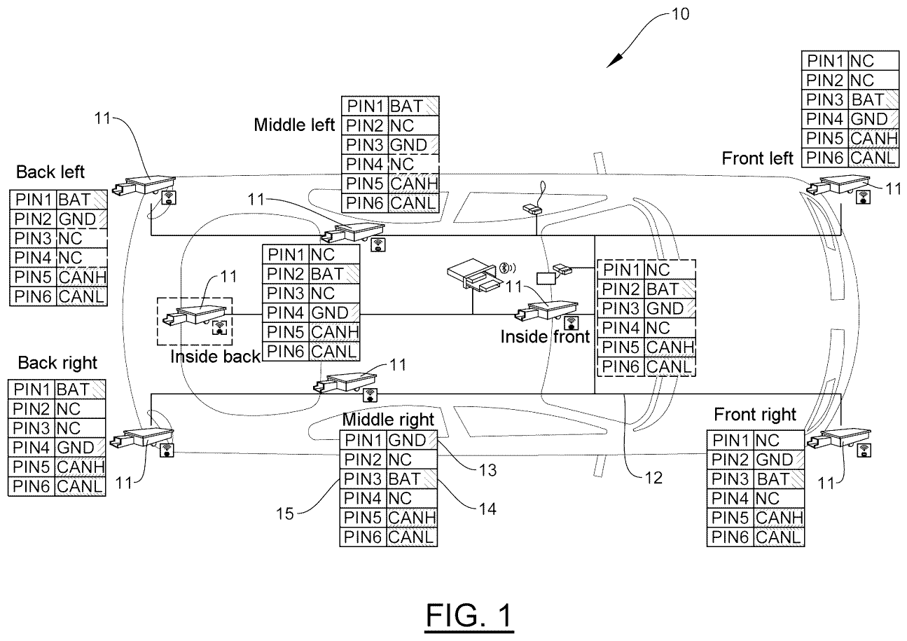

Examples of the first implementation will now be given with reference to FIGS. 1 to 6.

FIG. 1 shows an example of a vehicle 10 comprising a central power supply having connectors, each in a different position in the vehicle from among a predetermined plurality of positions. In this example, as shown in the figure, the predetermined plurality of positions in the vehicle comprises six outside positions which are defined in the length and the width of the vehicle (“front left”, “front right”, “middle left”, “middle right”, “back left” and “back right”) and two inside positions (“inside front” and “inside back”). In each position, the central power supply comprises a connector to which a peripheral 11 is connected. In this example, each group consists of a single connector and each group therefore corresponds to a unique respective position in the vehicle, that is to say one of the six outside positions or of the two inside positions. The vehicle comprises eight connectors, and therefore eight groups, each of one connector. Each peripheral 11 is connected to the central power supply via a respective connector by virtue of a wired network 12 connecting each of the connectors to the central power supply.

Each peripheral is adapted to be connected to each connector, that is to say to the one to which it is connected and all the others. Each connector comprises a connection interface 15 and each peripheral 11 comprises a connection interface which is able to be connected to the connection interface 15 of each of the connectors according to a predetermined arrangement. The polarity of connection in each connector is defined by the arrangement. The peripherals comprise the same sets of poles. The poles of the peripherals are arranged in the same manner in the connection interfaces of the peripherals. The connectors to the poles of the power supply are, for their part, arranged differently in the various interfaces of the connectors.

The central power supply comprises a set of poles and the connection interface of each connector comprises a set of connection points. In this example, the central power supply comprises a power supply pole 14 (“BAT”) and a ground pole 13 (“GND”) and the connection interface 15 of each connector comprises six connection points (“PIN1”, “PIN2”, “PIN3”, “PIN4”, “PIN5” and “PIN6”). In other examples, the central power supply may comprise a number of poles other than two and the connection interface of each connector may comprise a different number of connection points. The number of connection points of each connector may be less than or equal to the number of poles of the central power supply.

The set of poles of the central power supply is electrically connected to the set of connection points of the connection interface of each connector in each respective plurality of connectors according to a unique correspondence for each group. In this example, each pole of the central power supply 13, 14 is electrically connected to a respective connection point of the connection interface of each connector. For example, for the “middle right” position, the ground pole 13 (“GND”) of the central power supply is electrically connected to the first connection point (“PIN1”) of the connection interface of the connector, and the power supply pole 14 (“BAT”) is connected to the third connection point (“PIN3”). For the “front right” position, the ground pole (“GND”) is connected to the second connection point (“PIN2”) and the power supply pole (“BAT”) is connected to the third connection point (“PIN3”). The other connection points, that is to say the ones which are connected neither to the ground nor to the power supply, are not connected (“NC”).

For each peripheral and each connector in its respective plurality of connectors, the connection interface of the peripheral is able to be connected to the connection interface of the connector according to a predetermined arrangement. In other words, the connection interfaces of each peripheral and of each connector in its respective plurality of connectors are arranged so that the order in which the connection points of the connector are connected to connection points of a peripheral (when this peripheral is connected to the connector) is the same for all the peripherals adapted to be connected to this connector. For example, the connection interface of the peripheral and the connection interface of the connector may have a complementary shape so that they interlock with one another only in a single direction. Alternatively or additionally, the interfaces may comprise a distinctive sign indicating a direction of connection, such as a colour or an etching.

In the example of FIG. 1, each group consists of a single connector, and each peripheral is therefore able to be connected to each connector. In other examples, when the groups are formed of several connectors, a peripheral may be able to be connected to a first connector of a group but not be adapted to be connected to a second connector of this group. In this case, the arrangement of the connection interface of the peripheral and of the connection interface may, for example, make it incompatible to connect the peripheral to the second connector.

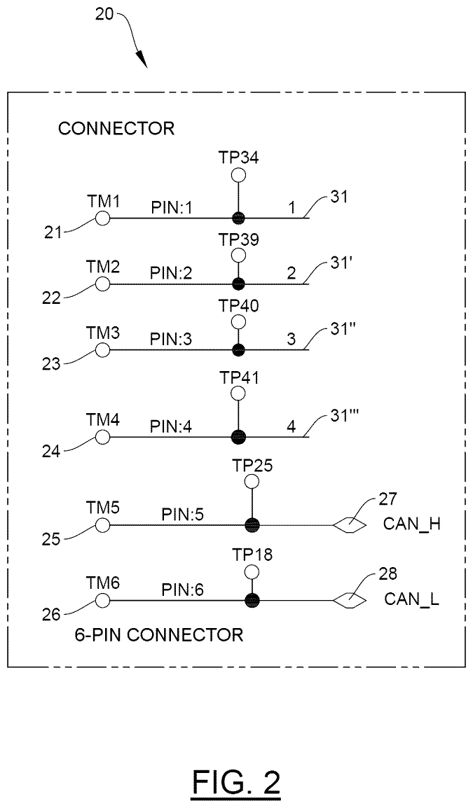

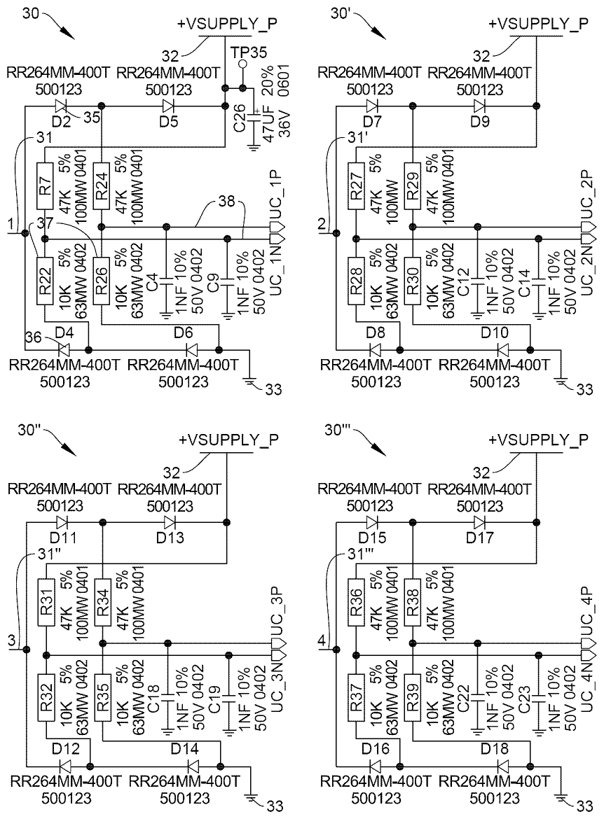

FIG. 2 shows an example of a connector 20 of the central power supply of the vehicle of FIG. 1. The connector 20 represents any one of the connectors discussed with reference to FIG. 1. One of the peripherals 11 of the vehicle is connected to this connector 20. The connector comprises a connection interface comprising six connection points 21, 22, 23, 24, 25, 26. The four first connection points 21, 22, 23, 24 (“PIN1”, “PIN2”, “PIN3” and “PIN4”) are used to define the polarity of connection on the basis of the power supply of the peripheral connected to the connector. The peripheral comprises four sub-circuits, which each comprise a distinct respective connection terminal 31, 31′, 31″, 31′″. When the peripheral is connected to the connector 20, each of these connection terminals 31, 31′, 31″, 31′″ is connected to a respective connection point 21, 22, 23, 24. The sub-circuits of the peripheral are described in more detail with reference to FIG. 3.

The polarity of connection is now discussed. The polarity of connection is a particular correspondence between the poles of the central power supply and the connection terminals of the peripheral. This particular correspondence for each connector of the same group is defined by the correspondence of the poles of the central power supply to the connection points of the connection interface of the connector and by the predetermined arrangement of the connection interfaces of the connector and of the peripheral.

For example, with reference to FIG. 2, the correspondence between the poles of the central power supply (“BAT” and “GND”) and the connection terminals of the peripheral is defined by the correspondence of the poles of the central power supply to the connection points (21, 22, 23, 24, 25, 26) of the connection interface of the connector and by the predetermined arrangement of the connection interfaces of the connector and of the peripheral which fixes the order in which the connection points 21, 22, 23, 24, 25, 26 are connected to the connection terminals 31, 31′, 31″, 31′″ of the peripheral connected to the connector 20.

For the connector in the “back right” position of FIG. 1, the power supply pole “BAT” is connected to the first connection point “PIN1”, and the ground pole “GND” to the fourth connection point “PIN4”. The connection terminal 31 is therefore electrically connected to the power supply pole, and the connection terminal 31′″ to the ground pole “GND”. For the “middle right” connector, the power supply pole “BAT” is connected to the third connection point “PIN3”, and the ground pole “GND” to the first connection point “PIN1”. The connection terminal 31 is therefore connected to the ground “GND”, and the connection terminal 31″ to the power supply pole “BAT”. The correspondence between the poles of the central power supply and the connection terminals of the peripheral therefore differs for each of the positions in the vehicle.

The connection interface of the connector 20 depicted in FIG. 2 also comprises two last connection points 25, 26 (“PIN5” and “PIN6”) which may be connected to two connection points 27, 28 of the peripheral (in this example, “CAN_H” and “CAN_L”). These two connection points may be used for implementing other functions, such as communicating or exchanging data between the peripheral connected to the connector and the vehicle.

FIG. 3 shows a first example of an electrical circuit of a peripheral. In this first example, the electrical circuit comprises four sub-circuits 30, 30′, 30″, 30′″. Each sub-circuit comprises a distinct respective connection terminal 31, 31′, 31″, 31′″, a first common pole 32 (“+VSUPPLY_P”) and a second common pole 33 (the ground). Each sub-circuit 30, 30′, 30″, 30′″ is configured to stop current from flowing from the first pole 32 to the connection terminal of the sub-circuit and to stop current from flowing from the connection terminal of the sub-circuit to the second pole 33. For each sub-circuit, the current therefore cannot flow directly from the first pole 32 to the connection terminal of the sub-circuit and from the connection terminal of the sub-circuit to the second pole 32. Each sub-circuit 30, 30′, 30″, 30′″ is also configured so that, when the current flows from the connection terminal to the first pole 32, then the connection terminal and the first pole 32 are at the same potential and, when the current flows from the second pole 33 to the connection terminal, then the second pole 33 and the connection terminal are at the same potential.

The peripheral is adapted so that, for each connector, the connection terminal of each sub-circuit 31, 31′, 31″, 31′″ is connected to a distinct respective connection point of the connection interface of the connector (that is to say one of the connection points 21, 22, 23, 24 with reference to FIG. 2). The connection terminal of one sub-circuit is therefore connected to the connection point connected to the power supply pole and the connection terminal of another sub-circuit is therefore connected to the connection point connected to the ground pole. For example, when the peripheral is connected to the connector located in the “middle right” position with reference to FIG. 1, the ground pole “GND” of the central power supply is electrically connected to the first connection point 21 “PIN1” and the power supply pole “BAT” is connected to the third connection point 23 “PIN3” of the connection interface of the connector. The connection terminal 31″ of the sub-circuit 30″ is therefore electrically connected to the power supply pole and the connection terminal 31 of the sub-circuit 30 is electrically connected to the ground pole. For example, also, when the peripheral is connected to the connector located in the “front right” position, the ground pole “GND” is electrically connected to the second connection point 22 (“PIN2”) and the power supply pole (“BAT”) is connected to the third connection point 23 (“PIN3”). The connection terminal 31″ of the sub-circuit 30″ is therefore electrically connected to the power supply pole and the connection terminal 31′ of the sub-circuit 31′ is electrically connected to the ground pole. For each of the other positions, also, the set of poles of the central power supply is electrically connected to the set of connection points of each other connector according to a unique correspondence.

The sub-circuit 30 will now be discussed in more detail. The other sub-circuits 30′, 30″ and 30′″ comprise the same features as the ones which will now be discussed with reference to the sub-circuit 30. The sub-circuit 30 comprises a first diode 35 configured to stop current from flowing from the first pole 32 to the connection terminal 31 and a second diode 36 configured to stop current from flowing from the connection terminal 31 to the second pole 33. The sub-circuit 30 comprises two resistors 37. The electrical measurement comprises a measurement of voltage across the terminals of each of these two resistors 37. The sub-circuit 30 comprises two measurement points 38 (“UC_1P” and “UC_1N”). These two measurement points 38 make it possible to measure the voltage across the terminals of each of the two resistors 37. The electrical measurement comprises, for each sub-circuit, a measurement of voltage at these two measurement points 38. The resistors may be different. The measurements of voltage across the terminals of each of the resistors may be different.

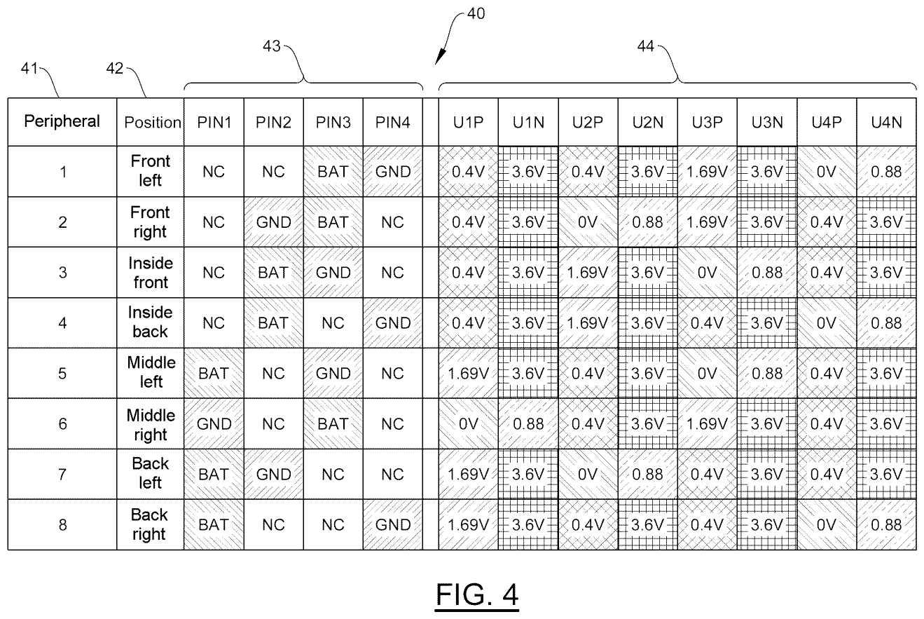

FIG. 4 shows an example of the variation in signature exhibited by the measurement in accordance with the polarity of connection for the first example of an electrical circuit of FIG. 3. In this example, each of the peripherals of FIG. 1 comprises the electrical circuit depicted in FIG. 3. The variation in signature according to the polarity of connection is illustrated in a table indicating, in columns, for each peripheral 41, the position of the peripheral 42, the polarity of connection induced by the connector to which the peripheral is connected and the measurements of voltage 44 across the terminals of each resistor. Each row of the table corresponds to one of the peripherals of FIG. 1. The measurements of voltage 44 across the terminals of each resistor which are indicated are theoretical measurements, that is to say measurements expected taking account of the polarity of connection and of the circuit of each of the peripherals. In accordance with the correspondence of the poles of the power supply and of the connection points of the peripheral, that is to say in accordance with the connector to which the peripheral is connected, the values of voltage across the terminals of the resistors of each sub-circuit are different, which makes it possible to obtain, for each peripheral, a distinctive signature. All of the measurements of voltage (“U1P” to “U4N”) are unique for each position, which makes it possible to determine, on the basis of this set of measurements of voltage, which connector each peripheral is connected to, and therefore to deduce therefrom the position of the peripheral in the vehicle. Determining the position may comprise comparing the measurement value with the expected theoretical measurement value, for example using error intervals for each theoretical value.

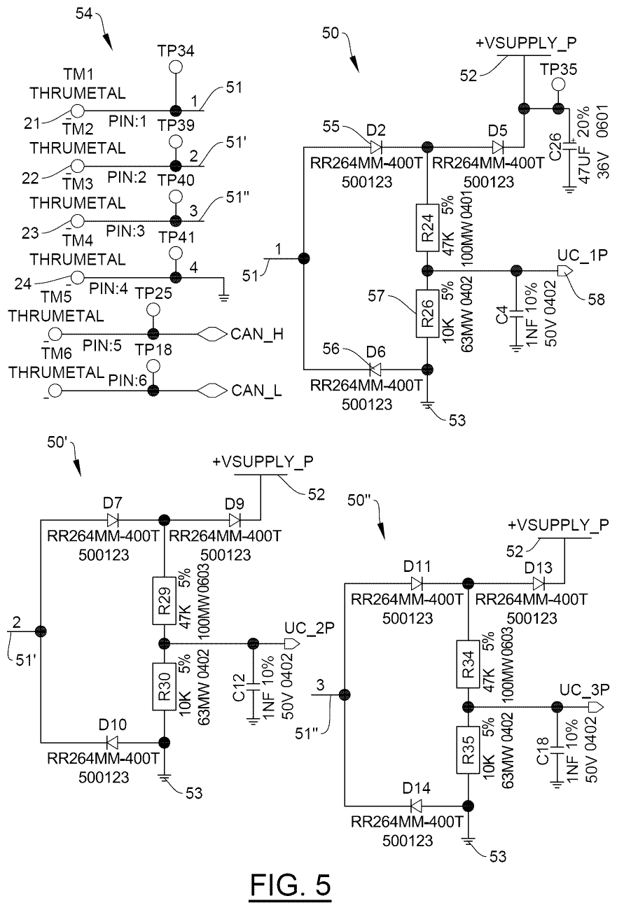

FIG. 5 shows a second example of an electrical circuit of a peripheral. The second example of an electrical circuit is a simplified model which comprises fewer components than the first example of FIG. 3. This second example makes a gain in compactness possible. In this second example, the electrical circuit comprises three sub-circuits 50, 50′, 50″, which each comprise a distinctive respective connection terminal 51, 51′, 51″, a first common pole 52 (“+VSUPPLY_P”) and a second common pole 53 (the ground). Each sub-circuit is configured to stop current from flowing from the first pole 52 to the connection terminal (51, 51′ or 51″, respectively) and to stop current from flowing from the connection terminal to the second pole 53, and so that, when the current flows from the connection terminal to the first pole 52, then the connection terminal and the first pole 52 are at the same potential, and, when the current flows from the second pole 53 to the connection terminal, then the second pole 53 and the connection terminal are at the same potential.

The figure also shows the connection 54 of the connection interface of the connector to the connection interface of the peripheral. The connection terminals of the sub-circuits 51, 51′, 51″, 51′″, are connected to one of the three first connection points 21, 22, 23 of the connection interface of the connector. The fourth connection point 24 is connected to the ground. For each connector, the connection terminal of one of the three sub-circuits is connected to the connection point connected to the power supply pole and the connection terminal of another of the three sub-circuits is connected to the connection point connected to the ground pole. For example, when the peripheral is connected to the connector located in the “middle right” position, as discussed with reference to FIG. 1, the ground pole “GND” of the central power supply is electrically connected to the first connection point 21 (“PIN1”) and the power supply pole (“BAT”) is connected to the third connection point 23 (“PIN3”) of the connection interface of the connector. The connection terminal 51″ of the sub-circuit 50″ is therefore electrically connected to the power supply pole and the connection terminal 51 of the sub-circuit 50 is electrically connected to the ground pole. For example, also, when the peripheral is connected to the connector located in the “front right” position, the ground pole “GND” is electrically connected to the second connection point 22 (“PIN2”) and the power supply pole (“BAT”) is connected to the third connection point 23 (“PIN3”). The connection terminal 51″ of the sub-circuit 50″ is therefore electrically connected to the power supply pole and the connection terminal 51′ of the sub-circuit 51′ is electrically connected to the ground pole. For each of the other positions, also, the set of poles of the central power supply is electrically connected to the set of connection points of each other connector according to a unique correspondence.

The sub-circuit 50 will now be discussed in more detail. The sub-circuits 50′ and 50″ comprise the same features as the ones which will now be discussed for the sub-circuit 50. The sub-circuit 50 comprises a first diode 55 configured to stop current from flowing from the first pole 52 to the connection terminal 51 and a second diode 56 configured to stop current from flowing from the connection terminal 51 to the second pole 53. The sub-circuit 50 comprises a resistor 57. The electrical measurement comprises a measurement of voltage across the terminals of this resistor 57. The sub-circuit 50 comprises a measurement point 58 (“UC_1P”) which makes it possible to measure the voltage across the terminals of the resistor 57. The electrical measurement comprises, for each sub-circuit, a measurement of voltage at this measurement point 58.

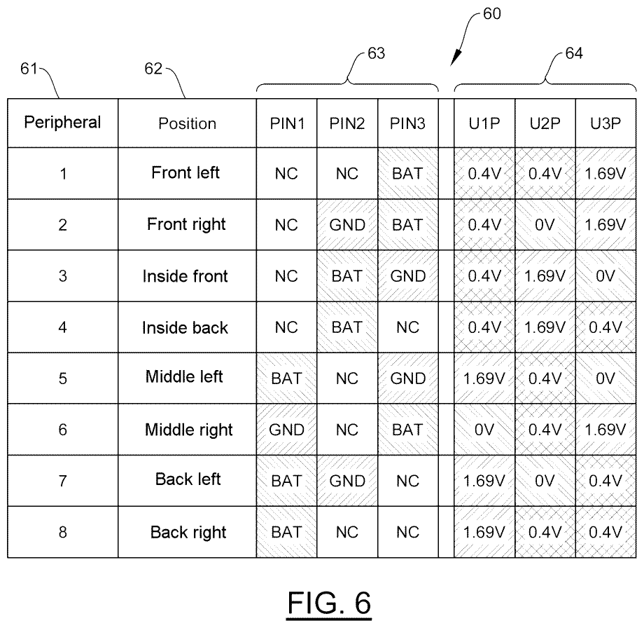

FIG. 6 shows an example of the variation in signature in accordance with the polarity of connection for the second example of an electrical circuit of FIG. 5.

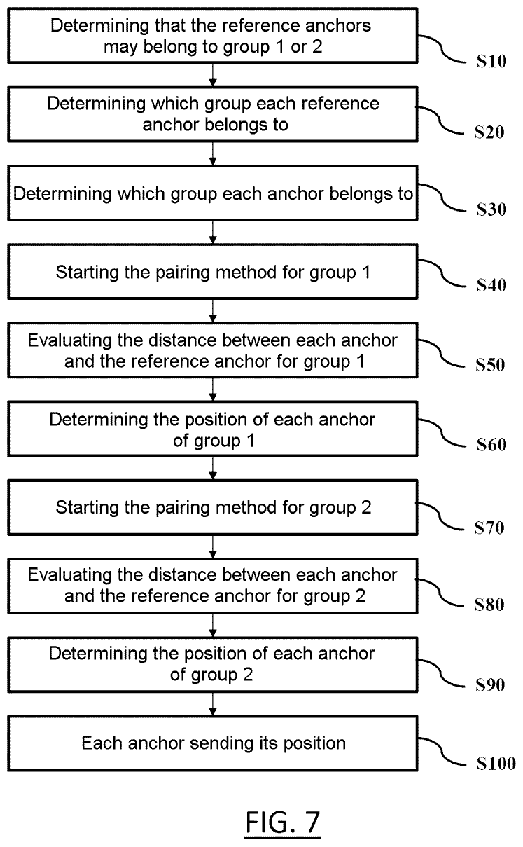

Examples of the second implementation will now be given with reference to FIGS. 7 to 10.

In these examples of the second implementation, one peripheral of each group is a reference peripheral. Each group comprises several connectors and the method comprises, for each group, providing the position of the reference peripheral of the group, relatively locating each other peripheral of the group, and determining the position of each other peripheral in accordance with the relative location and with the position of the reference peripheral. Each peripheral of a group may be interchanged with a peripheral of another group. The reference peripheral of each of the groups may be interchanged with the reference peripheral of each of the other groups. The other peripherals of each group (other than the reference one) may be interchanged with each other and may therefore be interchanged with the other peripherals of the other groups (the ones which are not reference ones).

FIG. 7 shows an example of determining the position of each anchor. In this example, the vehicle comprises two groups (1 and 2). Firstly, the method determines S10 that the reference anchors may belong to each of these two groups 1 or 2. Next, the method determines S20 which group each reference anchor belongs to. For this purpose, the method may use the measurement value of the reference anchor, as for the other anchors. The method therefore determines the reference anchor belonging to group 1 and the reference anchor belonging to group 2. Determining which group each reference anchor belongs to makes it possible to provide the position of each reference anchor. For example, the position of the reference anchor for each group may be predetermined. On the basis of the group to which the reference anchor belongs, the method may therefore determine the position of the reference anchor.

The method next comprises determining S30 which group each other anchor belongs to (that is to say anchors which are not reference ones). The method next determines, for each group, the relative position of each other anchor with respect to the reference anchor. The method comprises, for group 1, pairing S40 the anchors, measuring S50 the distance between each other anchor and the reference anchor and determining S60 the relative position of each other anchor with respect to the reference anchor. For example, the method may compare the measured distances with predetermined distances. The predetermined distances may be prestored distances for each position of the group. For example, the method may prestore that a position is the closest to the reference anchor and therefore determine the position of the anchor from which the measured distance is the smallest. The method may determine the position of the other anchors in a similar manner, for example iteratively by each time eliminating the anchors the position of which has been determined. The distance between each other anchor and the reference anchor may be measured S50 by UWB communication. The measurement may be a time-of-flight measurement.

The method determines the position of each anchor of group 2 in a similar manner (S70, S80, S90). The method may determine the position of the anchors of group 1 and determine the position of the anchors of group 2 successively. Otherwise, the method may determine the position of the anchors of group 1 and of group 2 simultaneously in parallel for each group. The method may next comprise each anchor sending S100 its determined position, for example to a master unit.

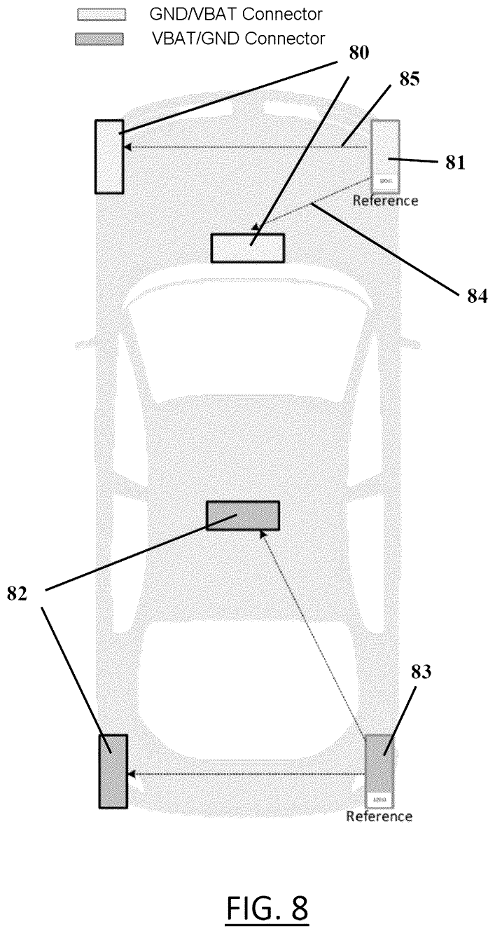

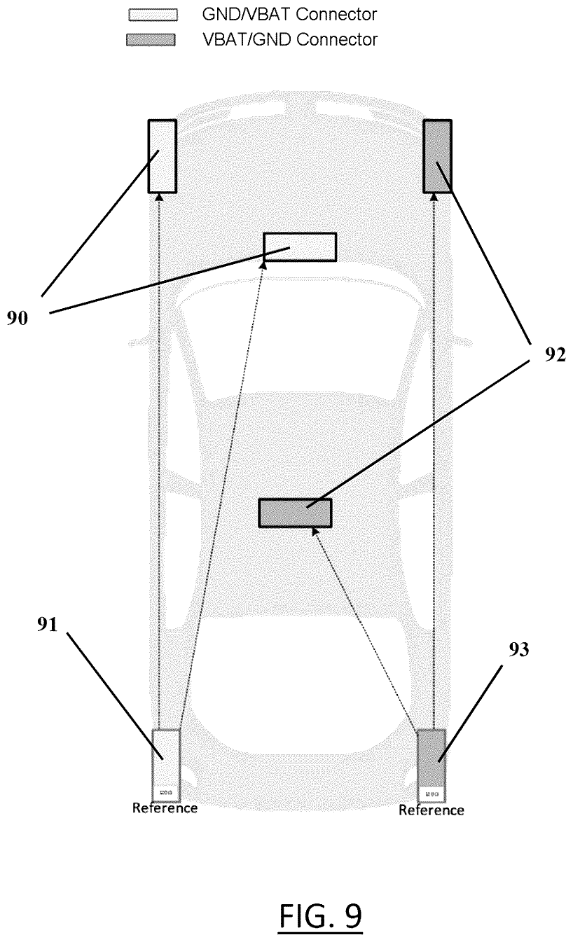

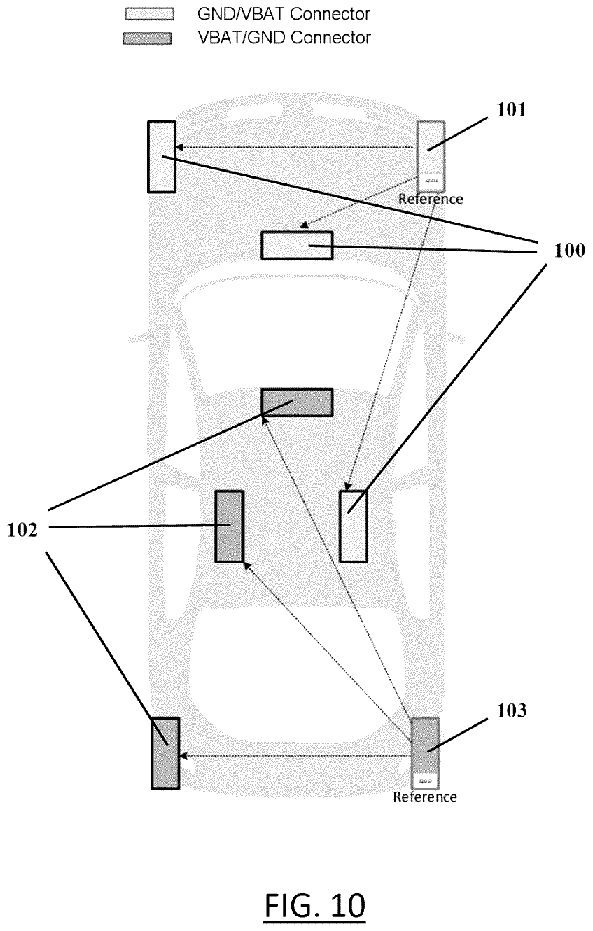

FIGS. 8, 9 and 10 show various examples of groups of connectors.

In the example of FIG. 8, the vehicle comprises six anchors split into two groups. The first group is formed of the anchors located at the front of the vehicle, and the second group anchors located at the back. For each group (1 and 2), one anchor is a reference anchor (81 for group 1 and 83 for group 2). Each group comprises two anchors which are not reference ones (80 for group 1 and 82 for group 2). The reference anchors are, in this example, positioned in the “front right” and “back right” positions. The position of the reference anchors within each group may be prestored.

The method may determine, firstly, which group the two reference anchors 81 and 83 belong to. After having determined which group each anchor belongs to, the method may therefore determine that the reference anchor belonging to the first group is in the “front right” position and that the reference anchor belonging to the second group is in the “back right” position. For example, the method may associate and store the identifier of the reference anchors with their position.

The method may next determine which group each of the other anchors belongs to. The method thus identifies that the anchors 80 belong to group 1, and the anchors 82 to group 2. The method may next, with the aid of the reference anchor identified for each group, determine the position of the other anchors of the group. For example, the method may measure, for group 1, the distance between each of the anchors 80 and the reference anchor 81, for example by UWB communication with time-of-flight measurement. The method may next deduce that the anchor with the shortest measured distance 84 is in the “middle front” position and the anchor with the longest measured distance 85 is in the “front left” position. The method may determine the position of each of the anchors of group 2 in a similar manner.

In the example of FIG. 9, the vehicle also comprises six anchors split into two groups. In this example, the groups of anchors are not formed in the front and back directions of the vehicle, but in the left and right directions of the vehicle. For each group (1 and 2), the anchor located at the back of the vehicle is the reference anchor (91 for group 1 and 93 for group 2). The anchors which are not reference ones (90 for group 1 and 92 for group 2) are split between the middle and the front of the vehicle.

In the example of FIG. 10, the vehicle comprises eight anchors which are split into two groups, with one reference anchor per group (101 for group 1 and 102 for group 2). In this example, each group comprises three anchors which are not reference ones (100 for group 1 and 102 for group 2). In order to distinguish each of these three anchors, the method may, for example, firstly, determine the position of the anchor furthest from the reference anchor and of the closest anchor. The method may next deduce, on the basis of the two anchors identified and of their respective position, that the third anchor (that is to say the last remaining unidentified one of the group) is positioned in the only position of the group of positions which has not been attributed, that is to say the one at a medium distance from the reference anchor.

1. A method for locating, in a vehicle, one or more peripherals,
the vehicle comprising a central power supply comprising connectors, each in a different position in the vehicle from among a predetermined plurality of positions,
the vehicle comprising at least two groups, each of one or more respective connectors,
wherein each peripheral is connected to the central power supply via a respective connector of a respective group,
wherein each peripheral is adapted to be connected to at least one respective connector of each other group,
wherein the connectors to which each peripheral is adapted to be connected together form a respective plurality of connectors, each defining a polarity of connection between the peripheral and the unique central power supply for each group,
the method comprising, for each peripheral:
taking an electrical measurement of the polarity of connection between the peripheral and the central power supply, and
determining, according to the value of the measurement, a group of one or more positions from among the predetermined plurality of positions of the peripherals.

2. The method according to claim 1,
wherein each connector comprises a connection interface and each peripheral comprises a connection interface, and, for each peripheral and each connector in its respective plurality of connectors, the connection interface of the peripheral is able to be connected to the connection interface of the connector according to a predetermined arrangement.

3. The method according to claim 2,
wherein the central power supply comprises a set of poles and the connection interface of each connector comprises a set of connection points,
wherein each pole of the central power supply is electrically connected to a respective connection point of the connection interface of each connector,
wherein the set of poles of the central power supply is electrically connected to the set of connection points of the connection interface of each connector in each respective plurality of connectors according to a unique correspondence for each group.

4. The method according to claim 2,
wherein the set of poles of the central power supply comprises a power supply pole and a ground pole,
wherein each peripheral comprises an electrical circuit including several sub-circuits,
wherein each sub-circuit comprises:
a distinct respective connection terminal,
a first common pole, and
a second common pole,
wherein each sub-circuit is configured to stop current from flowing from the first pole to the connection terminal and to stop current from flowing from the connection terminal to the second pole, and so that, when the current flows from the connection terminal to the first pole, then the connection terminal and the first pole are at the same potential, and, when the current flows from the second pole to the connection terminal, then the second pole and the connection terminal are at the same potential,
wherein each peripheral is adapted so that, for each connector in its respective plurality of connectors, the connection terminal of each sub-circuit is connected to a distinct respective connection point of the connection interface of the connector, with at least the connection terminal of one sub-circuit connected to the connection point connected to the power supply pole and the connection terminal of another sub-circuit connected to the connection point connected to the ground pole.

5. The method according to claim 4,
wherein each sub-circuit of each peripheral comprises a first diode configured to stop current from flowing from the first pole to the connection terminal and a second diode configured to stop current from flowing from the connection terminal to the second pole.

6. The method according to claim 4,
wherein each sub-circuit of each peripheral comprises a respective resistor,
the electrical measurement comprising, for each resistor, a respective measurement of voltage across the terminals of the respective resistor.

7. The method according to claim 1,
wherein each group consists of a single connector,
wherein each group corresponds to a respective position in the vehicle.

8. The method according to claim 1,
wherein each group comprises several connectors,
the method further comprising, for each group:
providing the position of a reference peripheral;
relatively locating each other peripheral; and
determining the position of each other peripheral in accordance with the relative location and with the position of the reference peripheral.

9. The method according to claim 8,
the relative location comprising a measurement of distance between each other peripheral and the reference peripheral.

10. The method according to claim 9,
wherein the measurement is a time-of-flight measurement.

11. A non-transitory computer readable medium comprising program instruction for causing a processor to perform the method of claim 1.

12. (canceled)

13. A peripheral adapted to be connected, via a connector, to a central power supply of a vehicle,
the peripheral being configured to implement the location method according to claim 1.

14. A system for a vehicle,
the system comprising a computer readable medium according to claim 11, and
a peripheral adapted to be connected, via a connector, to a central power supply of a vehicle and which stores the computer readable medium.
